(19) United States
(12) Patent Application Publication
(10) Pub. No.: US 2026/0169096 A1
(43) Pub. Date: Jun. 18, 2026

(54) CABLE WITH ABNORMALITY SIGN DETECTION FUNCTION

(71) Applicants: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(72) Inventors: Hirokazu KOMORI, Yokkaichi-shi (JP); Takahiro MURATA, Yokkaichi-shi (JP); Fujio SONODA, Osaka-shi (JP); Masato IZAWA, Osaka-shi (JP); Takumi OOSHIMA, Kanuma-shi (JP)

(73) Assignees: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(21) Appl. No.: 18/727,195

(22) PCT Filed: Jan. 16, 2023
(86) PCT No.: PCT/JP2023/000993

§ 371 Date: Jul. 8, 2024

(30) Foreign Application Priority Data
Jan. 28, 2022 (JP) 2022-011410

(51) Int. Cl. G01R 31/58

(52) U.S. Cl. CPC G01R 31/58

(57) ABSTRACT

A cable with an abnormality sign detection function that can detect signs leading to breakage in a wire by inputting an electrical signal, even without the use of an external ground potential. The cable contains a target wire containing a wire conductor and a wire covering that covers the conductor and a detection line containing a detection line conductor and a detection line covering that covers the detection line conductor, where the detection line conductor has a shorter flex life than the wire conductor, the detection line conductor contains, as elemental wires, inner elemental wires and outer elemental wires having a shorter flex life than the inner elemental wires, each of the inner elemental wires is configured as a bare wire that exposes a conductive material, and the outer elemental wires are arranged around a bundle of the inner elemental wires, insulated from the bundle of the inner elemental wires.

### TECHNICAL FIELD

The present disclosure relates to a cable with an abnormality sign detection function.

### BACKGROUND ART

Electric wires are installed and laid in various electrical and electronic devices, transportation equipment, buildings, and public facilities. With the long-term use of the wires, damage such as wire breakage may occur. For example, when an electric wire is subjected to repeated bending or vibration, a break may occur in a conductor contained in the wire due to metal fatigue. Damage such as wire breakage should desirably be detected at the stage when signs of the damage appear, such as at the stage when metal fatigue is in progress, before the damage actually occurs. If the damage can be detected at the stage when only the signs appear, it is possible to prevent the occurrence of problems caused by the wire damage, including functional failure of the device in which the wire is installed, by implementing measures such as replacement of the wire.

As an example of a cable which is intended for detection of signs of wire damage, Patent Document 1 discloses a cable with a wire disconnection detection function. The cable contains a detecting wire containing a conductor formed by twisting a plurality of strands, and a detected wire containing a conductor formed by twisting a plurality of strands, where a twist pitch of the conductor of the detecting wire is longer than that of the conductor of the detected wire. By making the twist pitch of the conductor of the detecting wire longer than that of the conductor of the detected wire, the flex life of the detecting wire is made to be shorter than that of the detected wire, which allows prediction of wire disconnection.

Patent Document 2 discloses a wire breakage detection device. The device contains an electric cable containing a plurality of electric wires, an electric shield layer covering the plurality of electric wires, and a sheath covering the electric shield layer; a wire breakage detection line that is provided on the electric shield layer, containing a conductor wire and an insulation layer covering the conductor wire; a voltage source electrically connected to the conductor wire; a first detector electrically connected to the conductor wire; and a second detector electrically connected to the electric shield layer. The flex life of the wire breakage detection line is set shorter than the flex life of the electric wires. Patent Document 2 describes that while a voltage is applied to the conductor wire of the wire breakage detection line by the voltage source, breakage of the electric shield layer is predicted based on detected signals of the first and second detectors.

Patent Document 3 discloses a cable with a wire breakage detection function. The cable contains a core wire containing a conductor and an insulator covering the conductor, and a wire breakage detection line. The wire breakage detection line contains a plurality of elemental wires, each containing a conductor wire and an insulation covering the conductor wire. The plurality of elemental wires consists of two or more types of elemental wires with different flex lives. Patent Document 3 states that the detection line can cause stepwise breaks since the detection line contains the elemental wires with different flex lives in combination. The document further states that by insulating the elemental wires in the detection line individually, the changes in resistance due to breaks of the elemental wires appear clearly, thus enabling more accurate detection of wire breakage.

### Citation List

### Patent Literature

Patent Document 1: JP 2013-182716 A
Patent Document 2: JP 2007-305478 A
Patent Document 3: JP 2007-299608 A

### SUMMARY OF INVENTION

### Technical Problem

As described in Patent Documents 1-3, if a target wire intended for detection of signs of breakage is accompanied by a detection line that breaks more easily by bending than the target wire, it is possible to detect signs of breakage in the target wire by monitoring the occurrence of breaks in the detection line. For monitoring the occurrence of breaks, a method can be employed where an electrical signal such as alternating current is input to the conductor of the detection line, and changes in a response signal obtained through reflection or transmission are monitored. In this method, it is necessary to set a ground potential to be used as a reference for the electrical signal and to ensure a return path for the electrical signal.

As the ground potential for detection of signs of wire breakage, a common ground potential of the device, such as an automobile, in which the electric wire is installed can be used. However, since various components mounted in the device are usually connected to the common ground potential of the device, noises originating from the components are often superimposed on the electrical signal for detecting the signs of wire breakage, thereby making accurate detection of the signs of wire breakage difficult. Another possible method is to provide a ground line dedicated to the detection line for detection of the signs of wire breakage, instead of using the common ground potential of the device. In this method, the influence of noises can be suppressed. However, the number of wires to be installed in the device increases, which may lead to increases in the complexity of the internal structure of the device and the mass of the device. If detection of signs of wire breakage can be performed by the detection line without the use of an external ground potential, such as the common ground potential of the device or the dedicated ground line, it would be possible to simplify the equipment required for detection of signs of wire breakage while keeping the influence of noises suppressed.

In view of the above, the objective is to provide a cable with an abnormality sign detection function that can detect signs leading to breakage in a wire by inputting an electrical signal, even without the use of an external ground potential.

### Solution to Problem

A cable with an abnormality sign detection function according to the present disclosure contains a target wire containing a wire conductor and a wire covering that covers the wire conductor; and a detection line containing a detection line conductor and a detection line covering that covers the detection line conductor. In the cable, the detection line conductor, as a whole, has a shorter flex life than the wire conductor. The detection line conductor contains, as elemental wires, inner elemental wires and outer elemental wires having a shorter flex life than the inner elemental wires. Each of the inner elemental wires is configured as a bare wire that exposes a conductive material. The outer elemental wires are arranged around a bundle of the inner elemental wires, insulated from the bundle of the inner elemental wires.

### Advantageous Effects of Invention

The cable with the abnormality sign detection function according to the present disclosure can detect signs leading to breakage in a wire by inputting an electrical signal, even without the use of an external ground potential.

### BRIEF DESCRIPTION OF DRAWINGS

FIG. 1 is a cross-sectional view of a cable with an abnormality sign detection function according to a first embodiment of the present disclosure.

FIG. 2 is a cross-sectional view of a detection line contained in the above-described cable with the abnormality sign detection function according to the first embodiment.

FIG. 3 is a cross-sectional view of a detection line contained in a cable with an abnormality sign detection function according to a second embodiment of the present disclosure.

FIG. 4 is a cross-sectional view of a detection line contained in a cable with an abnormality sign detection function according to a third embodiment of the present disclosure.

### DESCRIPTION OF EMBODIMENTS

### Description of Embodiments of Present Disclosure

First, embodiments of the present disclosure will be explained.

A cable with an abnormality sign detection function according to the present disclosure contains a target wire containing a wire conductor and a wire covering that covers the wire conductor; and a detection line containing a detection line conductor and a detection line covering that covers the detection line conductor. In the cable, the detection line conductor, as a whole, has a shorter flex life than the wire conductor. The detection line conductor contains, as elemental wires, inner elemental wires and outer elemental wires having a shorter flex life than the inner elemental wires. Each of the inner elemental wires is configured as a bare wire that exposes a conductive material. The outer elemental wires are arranged around a bundle of the inner elemental wires, insulated from the bundle of the inner elemental wires.

The above-described cable with the abnormality sign detection function contains the detection line that contains the detection line conductor having a shorter flex life than the wire conductor of the target wire. Thus, when loads are repeatedly applied to the cable by bending or vibration, the elemental wires contained in the detection line conductor are likely to break in a shorter period of time than the wire conductor of the target wire. When a break occurs in any of the elemental wires in the detection line, the break can be detected through an electrical measurement, such as a measurement of characteristic impedance, whereby signs of breakage can be detected appearing in the target wire before the breakage actually occurs in the target wire.

In the electrical measurement, the bundle of the inner elemental wires, among the two types of elemental wires contained in the detection line conductors, can be used as a ground line, and an electrical signal can be input to the outer elemental wires with reference to the ground potential determined as the potential of the ground line. Because the outer elemental wires have a shorter flex life than the inner elemental wires and further are arranged surrounding the inner elemental wires, the outer elemental wires break before the inner elemental wires when loads are repeatedly applied to the detection line by bending or vibration. Therefore, by using the bundle of the inner elemental wires as the ground line, it is possible to detect breaks of the outer elemental wires by the electrical measurement stably and to detect the signs of breakage in the target wire sensitively. Since the outer elemental wires and the inner elemental wires constitute the single detection line together, there is no need to connect the cable with the abnormality sign detection function to the common ground potential of the device in which the cable is installed or to provide an independent ground line outside the cable in order to detect the breaks of the elemental wires by the electrical measurement. As a result, the electrical measurement can be performed stably while avoiding the influence of noises from the common ground potential of the device and the increases in the required space and the mass due to the installation of the independent ground line. Furthermore, since the inner elemental wires are constituted as bare wires exposing the conductive material, the bundle of the inner elemental wires provides a particularly stable ground potential.

Moreover, in the cable with the abnormality sign detection function, if another ground potential, such as the common ground potential of the device or a separately provided ground line, is used instead of using the bundle of the inner elemental wires of the detection line conductor as a ground line, the inner elemental wires can also be employed to detect signs of breakage in the target wire, as well as the outer elemental wires. Since the inner elemental wires have a longer flex life than the outer elemental wires and are located more inside, the inner elemental wires are less likely to break than the outer elemental wires. However, if loads are repeatedly applied to the conductor by bending or vibration, the inner elemental wires may break after the outer elemental wires break. Therefore, it is possible to detect signs of breakage in the wire conductor in the target wire in a stepwise manner by performing an electrical measurement on the assembly of the outer and inner elemental wires using the other ground potential as a reference, and by detecting breaks of the outer elemental wires and subsequent breaks of the inner elemental wire, respectively.

Here, it is preferable that each of the outer elemental wires should contain a conductive material and an insulation layer that covers the conductive material, and the outer elemental wires should be insulated from each other. In this case, the insulation layers provided on the outer periphery of the outer elemental wires serve to ensure the insulation between the outer elemental wires and the bundle of the inner elemental wires. At the same time, the outer elemental wires are individually insulated from each other. Thus, when the outer elemental wires break in a stepwise manner one by one or several by several depending on the magnitude of the loads applied to the cable with the abnormality sign detection function, conduction in broken elemental wires is less likely to be reformed at the position of the breaks even if the broken wires come into contact with unbroken wires. Therefore, the measurement value obtained by the electrical measurement, such as the characteristic impedance, sensitively changes due to the stepwise breaks of the outer elemental wires. By detecting the stepwise breaks by the electrical measurement sequentially, it is possible to detect the signs of breakage in the target wire while judging the degree of urgency of the signs.

Alternatively, it is preferable that the bundle of the inner elemental wires should be surrounded by an insulating material, and the outer elemental wires should be arranged around the insulating material. In this case, the insulation between the inner elemental wires and the outer elemental wires can be secured by a simple configuration of just covering the bundle of the inner elemental wires with a continuous insulating material.

Alternatively, it is also preferable that the outer elemental wires should be divided into a plurality of groups, and each of the groups should be surrounded by an insulating material. In this case, the insulating material surrounding each of the plurality of groups of the outer elemental wires provides insulation between the groups of the outer elemental wires and further insulation between the outer elemental wires and the inner elemental wires. Due to the configuration where the outer elemental wires are divided into the plurality of groups and the groups are mutually insulated, when the outer elemental wires in one or some of the groups break, conduction is less likely to be reformed at the position of the breaks by contact of the broken outer elemental wires with those in the other groups. Therefore, the measurement value obtained by the electrical measurement, such as the characteristic impedance, exhibits sensitive changes due to the breaks of the elemental wires in a group-by-group manner. In other words, when all the elemental wires in one of the groups break, the breaks are clearly detected as a change in the electrical characteristics of the outer elemental wires. Thus, by detecting the stepwise breaks of the outer elemental wires in a group-by-group manner, it is possible to detect the signs of breakage in the target wire while judging the degree of urgency of the signs with a certain degree of accuracy.

It is preferable that the outer elemental wires should include multiple types of elemental wires having mutually different flex lives, and the outer elemental wires of each type should be insulated from those of the other types. In this case, breaks of the outer elemental wires occur in a sequential manner in which the elemental wires having a shorter flex life break earlier. Thus, the measurement value obtained by the electrical measurement on the outer elemental wires as a whole changes in a stepwise manner, first due to breaks of the outer elemental wires having a shorter flex life and then due to breaks of those having a longer flex life. By detecting these stepwise changes, it is possible to judge in detail the degree of loads applied to the cable and the degree of urgency of the signs of breakage in the target wire.

It is further preferable that among the multiple types of elemental wires as the outer elemental wires, the elemental wires having a shorter flex life should be located in a more exterior area within the detection line conductor. Elemental wires located in a more exterior area within the detection line conductor are subjected to greater loads by bending and are more likely to break. Therefore, by placing outer elemental wires having a shorter flex life in a more external area, the difference in ease of breaking among the outer elemental wires derived from the difference in the flex lives thereof is amplified by the arrangement of the elemental wires, whereby significant difference is made in the timing of breaks among the outer elemental wires, depending on the types thereof. As a result, the degree of urgency of the signs of breakage in the target wire can be judged clearly.

The inner and outer elemental wires should have mutually different flex lives preferably by having a difference in at least one of a constituent material and a diameter. Then, the difference in the flex life can easily be made between the inner and outer elemental wires.

The cable should preferably contain a power wire and a communication wire, each of which constitutes the target wire. In this case, the detection line can be used commonly to detect signs of breakage in both the power wire and the communication wire.

### Detailed Description of Embodiments of Present Disclosure

A detailed description of cables with abnormality sign detection functions according to embodiments of the present disclosure will now be provided, referring to the drawings. The cable with the abnormality sign detection function according to each embodiments of the present disclosure is a cable capable of detecting signs leading to damage in a target wire contained in the cable.

### Cable With Abnormality Sign Detection Function According to First Embodiment

### (1) Configuration of Cable With Abnormality Sign Detection Function

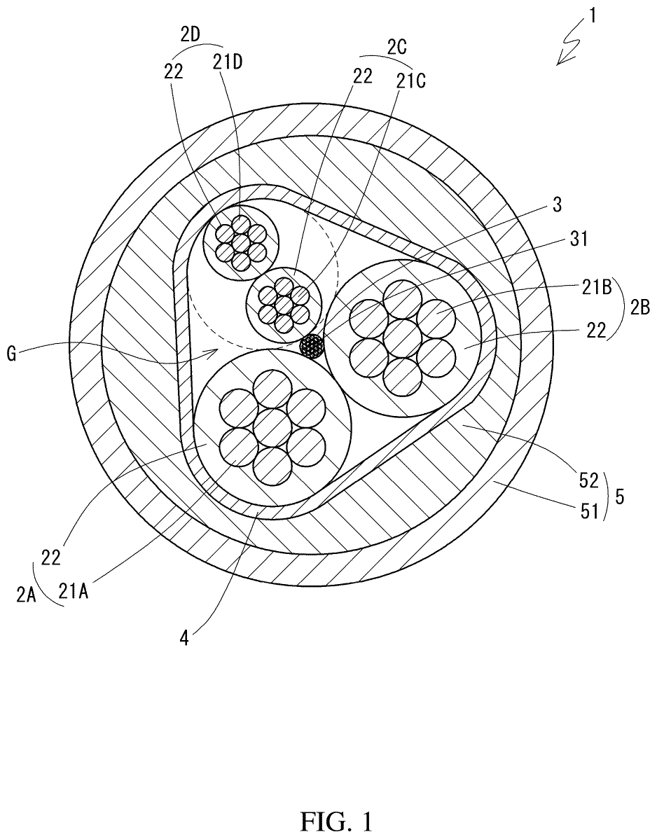

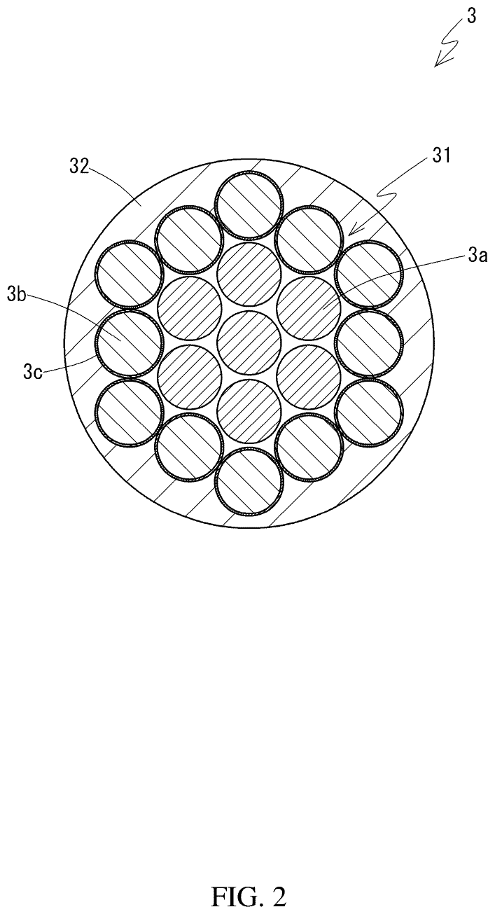

First, a cable with an abnormality sign detection function (hereinafter, also referred to simply as cable) according to a first embodiment of the present disclosure will be described. FIG. 1 displays the configuration of the cable with the abnormality sign detection function 1 according to the first embodiment of the present disclosure in a cross-sectional view perpendicular to the axial direction of the cable 1. The cable with the abnormality sign detection function 1 contains target wires 2 (2A-2D), a detection line 3, a tape layer 4, and a sheath 5. FIG. 2 shows a cross-section of the detection line 3.

The target wires 2 are wires that perform functions required in a device where the cable 1 is installed, such as power supply, voltage application, and communication. The target wires 2 are intended as targets for which signs of breakage should be detected in the cable 1. The number of target wires 2 is not specifically limited and may be one or more. Each of the target wires 2 contains a wire conductor 21 (21A-21D) configured as a conductor wire and a wire covering 22 that is made of an insulating material and covers the wire conductor 21. In the configuration shown in FIG. 1, the cable 1 contains four target wires 2A-2D. Two of the four wires are power wires 2A and 2B. The other two are communication wires 2C and 2D, which have a smaller conductor cross-sectional area than the power wires 2A and 2B, and are twisted with each other to form a twisted pair. In the figure, the outer edge of the twisted pair is indicated by a dashed line. This type of composite cable containing power wires 2A and 2B and communication wires 2C and 2D is used for an electric brake in an automobile, for example.

The detection line 3 is a wire that is configured to detect occurrence of signs of breakage in the target wires 2 by undergoing breaks in itself, as will be explained later about its function. The detection line 3 contains a detection line conductor 31 configured as a conductor wire and a detection line covering 32 that is made of an insulating material and covers the detection line conductor 31. The number of detection lines 3 contained in the cable 1 is not specifically limited and may be one or more. Though the cable 1 described mainly in the following sections contains only one detection line 3, the cable 1 may contain a plurality of detection lines 3 having detection line conductors 31 whose elemental wires are mutually different in the material, diameter, or number. The detection line covering 32 should preferably be provided as a component Separate from the detection line conductor 31 in view of ensuring the insulation of the detection line conductor 31; however, when insulation layers 3c or dividing insulation layers 3e are placed on the outer peripheries of the outer elemental wires 3b constituting the outer circumferential portion of the detection line conductor 31, the insulation layers 3c or 2e may function also as the detection line covering 32.

The detection line conductor 31 has a shorter flex life than the wire conductors 21 of the target wires 2. In the present specification, the flex life of a conductor or an elemental wire indicates the period of time until a break occurs in the conductor or elemental wire when the conductor or elemental wire is subjected to bending. The flex life can, for example, be evaluated as the number of bending cycles until the break occurs when the conductor or elemental wire is subjected to repeated cycles of bending at a predetermined angle. A larger number of bending cycles indicates a longer flex life (i.e., higher flex durability). As will be explained later, the detection line conductor 31 contains multiple types of elemental wires. The flex life of the detection line conductor 31 as a whole, that is, the flex life of the assembly of all the elemental wires, is shorter than the flex life of the wire conductor(s) 21 of the target wire(s) 2. When the cable 1 contains a plurality of target wires 2, the flex life of the detection line conductor 31 is shorter than the flex life of each of the wire conductors of the plurality of target wires 2. When the power wires 2A and 2B and the communication wires 2C and 2D are contained in the cable 1, the power wires 2A and 2B, which have a larger conductor cross-sectional area than the communication wires 2C and 2D, generally have a shorter flex life. The detection line conductor 31 has an even shorter flex life than the power wires 2A and 2B.

Examples of means to provide a difference in the flex lives of the conductors 21 and 31 between the target wires 2 and the detection line 3 are as follows: if the number of elemental wires constituting a stranded conductor having a fixed cross-sectional area is larger, the flex life of the conductor is longer. If the diameter of the elemental wires constituting the conductor is smaller, the flex life of the conductor is longer. If the conductive material composing the conductor exhibits higher flex durability as a material property, such as having higher Young's modulus, rigidity modulus, or bending strength, the flex life of the conductor is longer. If the twist pitch of elemental wires in the conductor is shorter, the flex life of the conductor is longer, as described in Patent Document 1.

In the cable 1, the target wires 2 and the detection line 3 are all assembled into a wire group G. In the wire group G, the relative positions of the target wires 2 and the detection line 3 are not specifically limited; however, it is preferable that the detection line 3 should be placed in the center, and the plurality of target wires 2 should surround the detection line 3. In this case, if the cable contains a plurality of detection lines 3, the detection lines 3 should preferably be placed together in the center. The detection line 3 and the target wires 2 may simply be assembled into a wire bundle; however, it is preferable that the bundle, including the detection line 3 in the center and the surrounding target wires 2, should be twisted as a whole. In this case, the detection line 3 in the center is also twisted.

The tape layer 4 is placed around the wire group G. The tape layer 4 serves to separate the target wires 2 and the detection line 3 constituting the wire group G from the sheath 5. The form and material of the tape layer 4 are not specifically limited; however, in a preferable example, a tape made of an insulating material such as paper or resin is spirally wound around the wire group G. The tape layer 4 contacts with the wire group G closely. In other words, the tape layer 4 is in contact with the outer circumferences of the wires facing the outermost circumference of the wire group G among the wires 2A-2D and 3 that constitute the wire group G (i.e., the outer circumferences of the target wires 2A, 2B, and 2D in FIG. 1).

The sheath 5 is configured as an extrusion-molded body of an insulator mainly containing a polymer material and surrounds the tape layer 4. The sheath 5 constitutes the outermost circumference of the entire cable 1. The sheath 5 contacts with the outer circumference of the tape layer 4 closely. The sheath 5 should preferably be in contact with the entire outer circumference of the tape layer 4 without having any gaps between the sheath 5 and the tape layer 4, except for unavoidable gaps. Though the sheath 5 may be composed of one or more layers, the sheath 5 described in the figure contains two layers: an outer layer 51 and an inner layer 52. The outer layer 51 is made of a material having higher mechanical properties, such as higher abrasion resistance, than the inner layer 52. In the cable 1, the tape layer 4 may be omitted. In this case, the sheath 5 is formed as an extrusion-molded body in direct contact with the outer circumference of the wire group G. Since the sheath 5 is formed as an extrusion-molded body and in close contact with the outer circumference of the wire group G optionally via the tape layer 4, the positional relationship between the target wires 2 and the detection line 3 is hard to be changed, which allows the detection line 3 to detect the signs of breakage in the target wires 2 accurately with sensitivity independent from the position and timing.

### (2) Configuration of Detection Line Conductor

Next, detection line conductor 31, contained in the detection line 3 in the cable with the abnormality sign detection function 1, will be described. The detection line conductor 31 is configured as an assembly of a plurality of elemental wires (i. e., a plurality of solid wires made of conductive materials). The conductor 31 is not composed of all identical elemental wires but includes a plurality of inner elemental wires 3a and a plurality of outer elemental wires 3b. The outer elemental wires 3b have a shorter flex life than the inner elemental wires 3a.

In the cable 1 according to the present embodiment, a plurality of inner elemental wires 3a is assembled in the center, forming a bundle. Around the bundle of the inner elemental wires 3a, a plurality of outer elemental wires 3b is placed. In the configuration shown in the figure, the outer elemental wires 3b are arranged in a layer surrounding the bundle of the inner elemental wires 3a. It is preferable that no other elemental wires or members should be interposed between the inner wires 3a and the outer wires 3b, except for the insulation layers 3c surrounding the outer elemental wires 3b. In the detection line conductor 31, twisting should preferably be applied to the entire assembly of the inner elemental wires 3a and the outer elemental wires 3b.

As described above, the outer elemental wires 3b have a shorter flex life than the inner elemental wires 3a. The outer elemental wires 3b and the inner elemental wires 3a may have mutually different flex lives by having mutual difference in at least one of the constituent material and diameter. As for the difference in the constituent material, the inner elemental wires 3a may be made of a material having higher flex durability as a material property, such as having higher Young's modulus, rigidity modulus, or bending strength, than the outer elemental wires 3b. As for the difference in the diameter, the inner elemental wires 3a may have a smaller diameter than the outer elemental wires 3b. Preferably, the inner elemental wires 3a and the outer elemental wires 3b should differ from each other at least in the constituent material. In this case, the inner elemental wires 3a should be made of a material having higher flex durability. For example, as conductive materials preferably used for the elemental wires, copper (i.e., soft copper) can be used for the outer elemental wires 3b, while a copper alloy can be used for the inner elemental wires 3a. For another example, aluminum can be used for the outer elemental wires 3b, while an aluminum alloy can be used for the inner elemental wires 3a. For yet another example, a copper alloy or aluminum alloy having relatively low flex durability can be used for the outer elemental wires 3b, while another copper alloy or aluminum alloy having lower flex durability can be used for the inner elemental wires 3a.

Each of the inner elemental wires 3a is configured as a bare wire (including a plated metal wire; the same applies throughout the present specification). In other words, each of the inner elemental wires 3a has no insulation layer around the periphery thereof. Instead, a conductive material constituting the inner elemental wire 3a is directly exposed. In the detection line conductor 31, the plurality of inner elemental wires 3a, each configured as a bare wire, are assembled to form a bundle. Conduction is formed between the inner elemental wires 3a.

Each of the outer elemental wires 3b may be a bare wire or has an insulation layer around the periphery thereof, as long as the outer elemental wires 3b are insulated from the bundle of the inner elemental wires 3a. However, in the present embodiment, each outer elemental wire 3b individually has an insulation layer 3c. In other words, the conductive material composing each of the outer elemental wires 3b is individually covered with the insulation layer 3c. The type and thickness of the insulation layer 3c are not specifically limited; however, the layer 3c should preferably be formed as an enamel coating layer. The insulation layers 3c surrounding the outer elemental wires 3b insulate the outer elemental wires 3b from the bundle of the inner elemental wires 3a. At the same time, the insulation layers 3c insulate the individual outer elemental wires 3b from each other.

### (3) Method for Detection of Wire Breakage

When the cable 1 described above is installed in a device and undergoes repeated bending or vibration during use, metal fatigue may be accumulated in the wire conductors 21 contained in the target wires 2, which may lead to breakage in the target wires 2. If breakage occurs in the target wires 2, the target wires 2 may no longer be able to perform the functions thereof, such as power supply or communication, whereby the device in which the cable 1 is installed may no longer be able to maintain the normal operations thereof. Furthermore, problems such as failure may occur in the device due to the breakage in the target wires 2.

However, the cable 1 according to the present embodiment contains the detection line 3 with the detection line conductor 31 having a shorter flex life than the wire conductors 21 of the target wires 2, in addition to the target wires 2, which perform designated functions within the device. If the cable 1 undergoes repeated bending or vibration, the detection line conductor 31, which has a shorter flex life, is likely to experience a break before the wire conductors 21. Occurrence of the break in the detection line conductor 31 indicates that the target wires 2 have also been subjected to loads due to the bending or vibration, and that metal fatigue has been accumulated in the wire conductors 21. Thus, the wire conductors 21 in the target wires 2 may also experience a break if the loads continue to be applied to the wire conductors 21. The break in the detection line conductor 31 can be detected by an electrical measurement, such as a measurement of characteristic impedance. Here, a break in the detection line conductor 31 is defined as break(s) of at least one of the elemental wires (i.e., outer elemental wires 3b and inner elemental wires 3a) constituting the detection line conductor 31.

Thus, through detection of the break in the detection line conductor 31, which has a shorter flex life, the presence of signs of breakage in the wire conductors 21 of the target wires 2 can be detected in advance, even before the breakage actually occurs in the target wires 2. If measures, such as replacement of the target wires 2 with new ones, are taken when the signs of breakage in the target wires 2 are detected, problems caused by the breakage in the target wires 2 can be prevented proactively. In the present specification, breakage in the wire conductors 21 of the target wires 2 may be referred to simply as breakage in the target wires 2.

Examples of the inspection methods for detecting signs of breakage in the target wires 2 using the detection line 3 in the cable 1 according to the present embodiment include a method where a characteristic impedance (or another electrical parameter obtained through an electrical measurement; the same applies hereafter) is measured while an electrical signal is input to the outer elemental wires 3b, using the bundle of the inner elemental wires 3a as a ground potential. For the measurement of the characteristic impedance in this method, a test signal with an alternating current component is input to the outer elemental wires 3b with a reference potential set on the inner elemental wires 3a. A response signal is detected by a reflection or transmission method, preferably by a reflection method.

If there is a break of any of the outer elemental wires 3b in the middle of the detection line conductor 31, reflection of the electrical signal occurs at the position of the break. The reflection causes a discontinuous change in the response signal. Therefore, if a change exceeding a standard value is observed in the measured characteristic impedance, it can be judged that a break has occurred in any of the outer elemental wires 3b, and that signs of breakage appear in the wire conductors 21 of the target wires 2. If the detection line conductor 31 has the form of a simple straight line, a break of any of the outer elemental wires 3b constituting the detection line conductor 31 typically causes a change in the value of characteristic impedance in the direction of an increase. The standard value of the characteristic impedance can be predetermined as a threshold value of the amount of change that should be attributed to a break in the outer elemental wires 3b, based on the measurement results when no break has occurred in the outer elemental wires 3b, for example. A change in the characteristic impedance may also be caused by damage to the outer elemental wires 3b that does not result in a break of any of the outer elemental wires 3b. Though the present specification deals with changes in the characteristic impedance caused by the break in the outer elemental wires 3b as the representative, damage to the outer elemental wires 3b other than the break can also be utilized for detection of the signs of breakage in the target wires 2 via changes in the characteristic impedance, in the same way as the break.

Furthermore, if a time-domain or frequency-domain method is employed for the measurement of the characteristic impedance, it is also possible to identify the position along the axial direction of the cable 1 where a break has occurred in the outer elemental wires 3b of the detection line conductor 31 due to application of the loads. In the case of the time-domain method, the position where a break has occurred in the outer elemental wires 3b can be determined by inputting a pulsed electrical signal to the outer elemental wires 3b and converting the time at which a change in the obtained characteristic impedance is observed into a position along the axial direction of the cable 1. In the case of the frequency-domain method, an electrical signal containing multiple frequency components is input to the outer elemental wires 3b, and the response signal is Fourier transformed to convert the information with respect to the frequency into the information with respect to the position along the cable 1. The measurement of the characteristic impedance of the detection line 3 should preferably be performed continuously or intermittently while the cable 1 is in use. Then, if signs of breakage occur in the wire conductors 21 of the target wires 2, the signs of breakage can be detected at an early stage and announced, for example, to a user of the device in which the cable 1 is installed. Alternatively, the measurement of the characteristic impedance of the detection line 3 may be performed at predetermined timings, such as timings of periodic inspections of the devices in which the cable 1 is installed.

In the detection line conductor 31 of the cable 1 according to the present embodiment, the outer elemental wires 3b have a shorter flex life than the inner elemental wires 3a. Therefore, when the detection line conductor 31 is repeatedly subjected to loads due to bending or vibration of the cable 1, the outer elemental wires 3b break before the inner elemental wires 3a. Furthermore, even if the elemental wires constituting the conductor are identical, the elemental wires located in a more exterior area within the conductor are subjected to greater loads when the conductor is bent, and are more likely to break even after a small number of bending cycles. This is because the elemental wires located on the outermost circumference of the conductor are bent with the smallest curvature radius on the inner side of the bent shape. Since the outer elemental wires 3b are arranged around the bundle of the inner elemental wires 3a in the detection line conductor 31 of the cable 1 according to the present embodiment, this arrangement amplifies the difference in flex life between the inner elemental wires 3a and the outer elemental wires 3b derived from the intrinsic properties of the elemental wires, thereby making the tendency more pronounced where the outer elemental wires 3b break after fewer bending cycles than the inner elemental wires 3a.

Thus, when the cable 1 according to the present embodiment is subjected to loads by bending or vibration, the inner elemental wires 3a in the detection line conductor 31 are less likely to break than the outer elemental wires 3b. Even when one or some of the outer elemental wires 3b break earlier due to application of repeated loads to the detection line conductor 31, the inner elemental wires 3a can be used stably as a ground line which serves as a reference potential for the measurement of characteristic impedance on the outer elemental wires 3b as long as all of the inner elemental wires 3a do not break. Meanwhile, the outer elemental wires 3b are likely to break in a relatively short period of time when subjected to repeated loads by bending or vibration, thereby sensitively detecting and alerting signs of breakage in the target wires 2 in the cable 1 through changes in the characteristic impedance caused by the breaks. Since the inner elemental wires 3a and the outer elemental wires 3b are insulated from each other, the inner elemental wires 3a, which function as a ground line, and the outer elemental wires 3b, which function as a means of detecting the signs of wire breakage by experiencing breaks, can coexist concentrically within the single detection line conductor 31.

Because the bundle of the inner elemental wires 3a in the detection line conductor 31 can be used as a ground line, there is no need to use an external ground potential, such as a common ground line of the device, such as an automobile, in which the cable 1 is installed or a dedicated ground line provided separately from the cable 1, for providing a ground potential and a return path for the electrical signal used for detection of signs of wire breakage. A common ground potential of a device, such as an automobile, is often connected with various components that constitute the device. Thus, the common ground potential is likely to convey noises originating from the components, thereby compromising the accuracy in the measurement of the characteristic impedance on the detection line 3. If a dedicated ground line is provided separately from the cable 1, a space is required to install the ground line, leading to complication of the internal configuration of the device and increase in the mass thereof.

Furthermore, in the detection line conductor 31 of the cable 1 according to the present embodiment, the inner elemental wires 3a are configured as bare wires. The inner elemental wires 3a are assembled together to form a bundle in the center of the detection line conductor 31. In other words, the inner elemental wires 3a electrically behave as a single conductor as a whole. Therefore, the inner elemental wires 3a function as a stable ground potential in the measurement of the characteristic impedance on the outer elemental wires 3b, thus allowing the measurement of the characteristic impedance to be continued stably with few noises. As a result, the signs of wire breakage can be detected with high accuracy. If each of the inner elemental wires 3a is covered by an insulation layer like the outer elemental wires 3b, the ground potential would not be stable, which may hinder accurate measurement of the characteristic impedance.

Meanwhile, the outer elemental wires 3b can be used for stepwise detection of the signs of wire breakage because the outer elemental wires 3b are individually covered with the insulation layers 3c. When the detection line conductor 31 is subjected to loads due to repeated bending or vibration, it is rare for all of the outer elemental wires 3b to break at once unless extremely large loads are applied. Instead, the outer elemental wires 3b tend to break sequentially, either one by one or several by several, increasing the number of broken outer elemental wires 3b gradually during a certain period of time. If a break occurs in the outer elemental wires 3b, the continuity of conduction in the broken outer elemental wires 3b is interrupted at the position of the break, whereby the value of the characteristic impedance measured for the outer elemental wires 3b as a whole changes according to the number of broken outer elemental wires 3b. However, if the outer elemental wires 3b do not have the insulation layers 3c and have conduction with each other, then even after an outer elemental wire 3b breaks, an adjacent unbroken outer elemental wire 3b will contact the broken outer elemental wire 3b and bridge the broken portion. Thus, the continuity of conduction is not interrupted in the broken outer elemental wire 3b (i.e., chattering, namely reformation of conduction, occurs). As a result, either no change occurs in the characteristic impedance of the outer elemental wires 3b, or only small or slow changes occur.

In contrast, in the present embodiment, the outer elemental wires 3b are individually insulated from each other by the insulation layers 3c. Thus, when an outer elemental wire 3b breaks, the state where the continuity of conduction is interrupted in the broken outer elemental wire 3b at the position of the break is maintained stably because of the insulation of the broken outer elemental wire 3b from the surrounding outer elemental wires 3b. As a result, an influence of the break of the outer elemental wire 3b arises in the value of characteristic impedance measured on the outer elemental wires 3b as a whole significantly and clearly. In other words, when stepwise breaks of the outer elemental wires 3b proceed as loads are cumulatively applied to the cable 1, such as by bending, the characteristic impedance of the outer elemental wires 3b exhibits clear stair-like changes, where the value of the characteristic impedance rapidly changes (typically increases) from a stable state, and settles into another stable state after the rapid change. Through the detection of the stair-like changes in the characteristic impedance, occurrence of stepwise breaks of the outer elemental wires 3b can be detected. The number of broken outer elemental wires 3b can also be estimated based on the number and amount of the stair-like changes. The stepwise progress of breaks of the outer elemental wires 3b indicates that cumulative application of loads progresses in the cable 1 as a whole due to repeated bending, for example. In other words, it means that the signs of breakage in the target wires 2 due to metal fatigue is getting more serious.

If a change exceeding the standard value is observed in the characteristic impedance measured on the outer elemental wires 3b as a whole, it can be judged that signs of breakage appear in the target wires 2, as described above. Furthermore, by detecting the stepwise breaks of the outer elemental wires 3b through the stair-like changes in the characteristic impedance, it is possible to determine the degree of urgency of the signs of breakage in the target wires 2 (i. e., how further additional loads will actually cause the breakage). Then, measures, such as issuance of alarms in accordance with the degree of urgency, can be taken in the device in which the cable 1 is installed, for example.

In the above-described configuration, the target wires 2 are inspected for signs of wire breakage with the use of the inner elemental wires 3a in the detection line 3 as a ground line. However, another inspection method for detecting signs of breakage in the target wires 2 with the detection line 3 in the cable 1 according to the present embodiment can be adopted in which the characteristic impedance is measured also on the inner elemental wires 3a. In this method, the characteristic impedance of the entire detection line conductor 31, including the outer elemental wires 3b and the inner elemental wires 3a, is measured with respect to a ground potential provided by the common ground potential of the device in which the cable 1 is installed or a ground line separately installed outside the cable 1. As described above, the outer elemental wires 3b, which have a shorter flex life, break first at a stage when the loads, such as those by bending, are not accumulated so heavily. Then, the inner elemental wires 3a, which have a longer flex life, break after more loads are applied cumulatively. The stepwise breaks of the outer elemental wires 3b and the inner elemental wires 3a cause stepwise changes in the characteristic impedance. By detecting the stepwise changes in the characteristic impedance, it is possible to judge the urgency of the signs of breakage in the target wires 2 due to application of the loads in a broader range that can not be covered only by the stepwise breaks of the mutually insulated outer elemental wires 3b. If the noises in the common ground potential of the device are low, or if the increase in space required by installation of a separate ground line does not cause a problem, this inspection method can be adopted.

### (4) Variant Embodiments

In the embodiment described above, a single type of elemental wires having a shorter flex life than the inner elemental wires 3a are used as the outer elemental wires 3b. However, it is also possible to use multiple types of elemental wires, as the outer elemental wires 3b, whose flex lives are all shorter than the flex life of the inner elemental wires 3a and different from each other. As the outer elemental wires 3b, elemental wires that have different flex lives by having a difference in at least one of the constituent material and the diameter can be used. If such multiple types of outer elemental wires 3b with different flex lives are used, the outer elemental wires 3b having a shorter flex life break earlier. As a result, the characteristic impedance of the outer elemental wires 3b as a whole exhibits changes corresponding to stepwise breaks of the elemental wires 3b more clearly and over a broader range of the degrees of application of loads. In particular, if the outer elemental wires 3b are arranged in multiple layers around the bundle of the inner elemental wires 3a, with the elemental wires having a shorter flex life located in a more exterior area within the detection line conductor 31, the difference between the flex lives of the multiple types of outer elemental wires 3b can further be amplified by the effect of the arrangement. Furthermore, when the cable includes multiple target wires 2 having different flex lives, like the power wires 2A and 2B and the communication wires 2C and 2D in the cable 1, the cable may be configured so that signs of breakage in the target wire(s) 2 with a shorter flex life, like the power wires 2A and 2B, are detected through breaks of outer elemental wires 3b with a shorter flex life among the multiple types of outer elemental wires 3b, whereas the signs of breakage in the target wire(s) 2 with a longer flex life, like the communication wires 2C and 2D, are detected through breaks of outer elemental wires 3b with a longer flex life among the multiple types of outer elemental wires 3b. When multiple types of outer elemental wires 3b with different flex lives are used, as in these configurations, the insulation layers 3c individually covering the outer elemental wires 3b not only insulate the outer elemental wires 3b from the bundle of the inner elemental wires 3a, but also insulate the outer elemental wires 3b of each type from those of the other types, and further mutually insulate the outer elemental wires 3b of each of the types.

Furthermore, in the embodiment described above, only one detection line 3 is contained in the cable with the abnormality sign detection function 1. However, multiple detection lines 3 may be contained in the cable. When multiple detection lines 3 are contained in the cable, the detection lines 3 may have detection line conductors 31 whose elemental wires 3a or 3b, especially outer elemental wires 3b, have mutually different flex lives. In this case, it is possible to judge the degree of urgency of the signs of breakage in the target wires 2 more clearly by measuring the characteristic impedances of the detection line conductors 31 individually. If breaks are detected in a detection line conductor 31 that contains elemental wires having a longer flex life, it can be judged that fatigue of the wire conductors 21 has progressed further, and thus that the urgency of the signs of wire breakage has grown higher. Moreover, when the cable includes multiple target wires 2 having different flex lives, like the power wires 2A and 2B and the communication wires 2C and 2D in the cable 1, the cable may be configured so that signs of breakage in the target wire(s) 2 with a shorter flex life, like the power wires 2A and 2B, are detected through breaks in a detection line conductor 31 containing elemental wires having a shorter flex life among the multiple detection line conductors 31, whereas the signs of breakage in the target wire(s) 2 with a longer flex life, like the communication wires 2C and 2D, are detected through breaks in another detection line conductor 31 containing elemental wires having a longer flex life among the multiple detection line conductors 31.

In the cable with the abnormality sign detection function 1 according to the first embodiment of the present disclosure and the variants thereof described above, the outer elemental wires 3b contained in the detection line conductor 31 are insulated individually by the insulation layers 3c.

Since the outer elemental wires 3b are thus insulated from each other, it is possible to detect changes in the characteristic impedance of the outer elemental wires due to stepwise breaks of the outer elemental wires 3b and to judge the degree of urgency of the signs of breakage in the target wires 2. However, if there is no need to detect the breaks of the outer elemental wires 3b one by one, individual insulation of the outer elemental wire 3b is not required. Instead, it is required only that each of the inner elemental wires 3a, which have a longer flex life, is configured as a bare wire exposing a conductive material, and the outer elemental wires 3b, which have a shorter flex life, are arranged around the bundle of the inner elemental wires 3a with insulated from the bundle of the inner elemental wires 3a. Then, by using the inner elemental wires 3a as a ground line, it is possible to detect signs of breakage in the target wires 2 through the indication by changes in the characteristic impedance of the outer elemental wires 3b due to breaks of the outer elemental wires 3b, without using an external ground potential. It is also possible, if an external ground potential is used as appropriate, to detect and judge the degree of urgency of the signs of breakage in the target wires 2 in at least two stages through stepwise changes in the characteristic impedance caused by breaks of the outer elemental wires 3b and the inner elemental wires 3a.

Such configurations in which the outer elemental wires 3b are not insulated individually are described next for cables with abnormality sign detection functions according to second and third embodiments of the present disclosure. In the second and third embodiments described below, forming insulation layers 3c around the individual outer elemental wires 3b is not precluded; however, from the viewpoint of simplicity of the configurations, it is preferable that such insulation layers 3c should not be formed. In the following description according to the second and third embodiments, detailed descriptions will be omitted for configurations common with the first embodiment described in detail above.

### Cable With Abnormality Sign Detection Function According to Second Embodiment

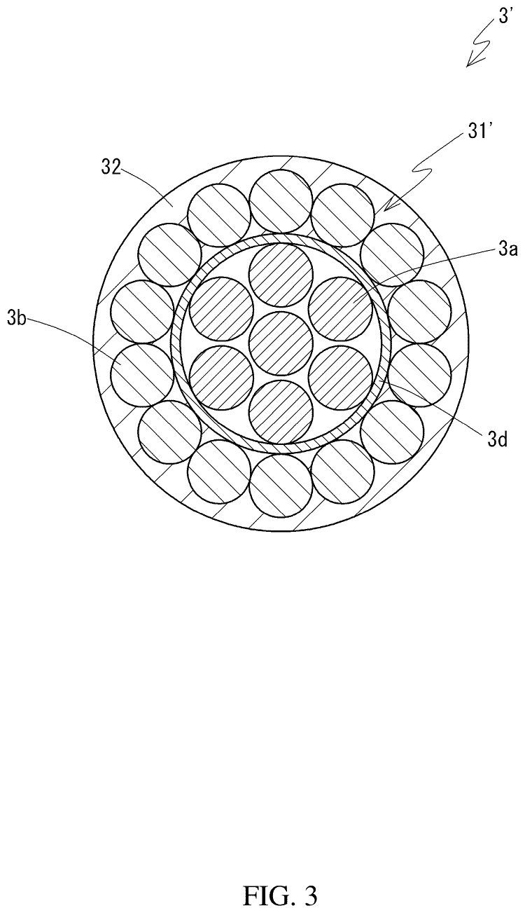

The cable with the abnormality sign detection function according to the second embodiment of the present disclosure has the same overall configuration as the cable 1 according to the first embodiment shown in FIG. 1. However, the configuration of the detection line conductor 31′ contained in the detection line 3′ differs from that of the detection line conductor 31 according to the first embodiment described above. FIG. 3 shows a cross-section of the detection line 3′ contained in the cable with the abnormality sign detection function according to the second embodiment.

The detection line conductor 31′ in the detection line 3′ according to the second embodiment also includes inner elemental wires 3a that have a longer flex life and outer elemental wires 3b that have a shorter flex life and surround the bundle of the inner elemental wires 3a. Here, both the inner elemental wires 3a and the outer elemental wires 3b are configured as bare wires exposing the conductive materials. In the present embodiment, the bundle of the inner elemental wires 3a assembled in the center of the detection line conductor 31′ is surrounded by an inner-outer insulation layer 3d made of an insulating material. The outer elemental wires 3b are arranged around the inner-outer insulation layer 3d. The outer elemental wires 3b are insulated from the bundle of the inner elemental wires 3a by the inner-outer insulation layer 3d. The inner-outer insulation layer 3d may take any form to cover the bundle of the inner elemental wires 3a, such as an extruded resin covering layer, an enamel coating layer, a sheet of insulating material such as paper or resin wrapped around the bundle, or a tube of such insulating material applied over the bundle.

When the detection line conductor 31′ is subjected to repeated bending or vibration, such as by bending of the entire cable, the outer elemental wires 3b break earlier than the inner elemental wires 3a because the outer elemental wires 3b have a shorter flex life and because the outer elemental wires 3b are arranged in a more exterior area in the detection line conductor 31′. By detecting the breaks of the outer elemental wires 3b through changes in the characteristic impedance, it is possible to detect that fatigue has been accumulated also in the wire conductors 21 of the target wires and that signs of wire breakage have occurred in the target wires. In an inspection for signs of wire breakage, a measurement of the characteristic impedance may be performed on the outer elemental wires 3b, using the inner elemental wires 3a as a ground line, or may be performed on the detection line conductor 31′ as a whole, which includes the outer elemental wires 3b and the inner elemental wires 3a together, using a ground potential outside the cable. In the former case, the use of an external ground potential can be eliminated, while in the latter case, it is possible to detect the signs of wire breakage in two stages through the phenomenon where the inner elemental wires 3a break after the outer elemental wires 3b when loads are repeatedly applied due to bending or vibration.

In the second embodiment, unlike the first embodiment described above, the outer elemental wires 3b are not insulated individually. Thus, even when the outer elemental wires 3b break in a stepwise manner, it is difficult to detect the stepwise breaks through changes in the characteristic impedance. Therefore, it is difficult to judge the degree of urgency of the signs of breakage in the target wires by using the stepwise breaks of the outer elemental wires 3b. However, since there is no need for individual insulation of the outer elemental wires 3b, the configuration of the detection line conductor 31′ can be simplified. Thus, the second embodiment can preferably be adopted when there is no need to judge the degree of urgency of the signs of wire breakage in detail. Multiple types of elemental wires having mutually different flex lives may be used as the outer elemental wires 3b also in the second embodiment. In this case, the multiple types of outer elemental wires 3b should be arranged so that the outer elemental wires 3b with a shorter flex life are located in a more exterior area in the detection line conductor 31′. Layers made of an insulating material similar to the inner-outer insulation layer 3d described above should be provided between the layers of the different types of outer elemental wires 3b to maintain the insulation of the outer elemental wires 3b of each type from those of the other types.

### Cable With Abnormality Sign Detection Function According to Third Embodiment

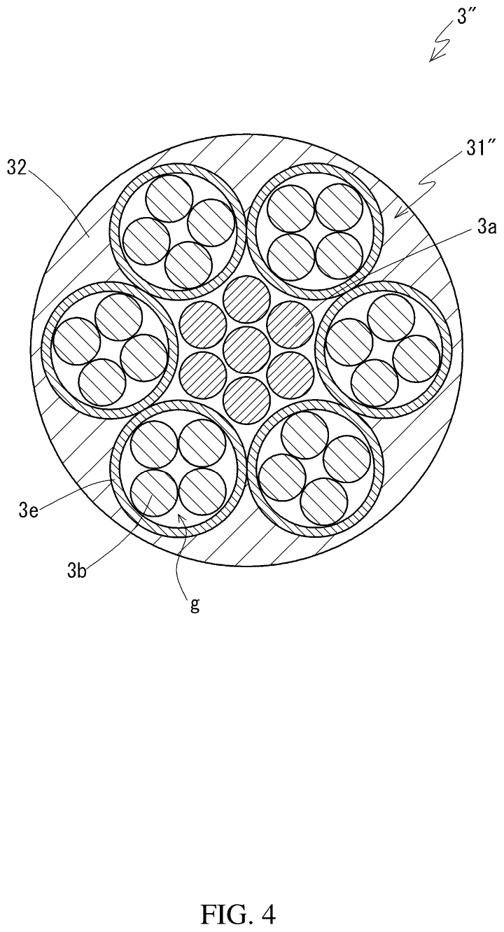

The cable with the abnormality sign detection function according to the third embodiment of the present disclosure also has the same overall configuration as the cable 1 according to the first embodiment shown in FIG. 1. However, the configuration of the detection line conductor 31″ contained in the detection line 3″ differs from the detection line conductors 31, 31′ according to the first and second embodiments described above. FIG. 4 shows a cross-section of the detection line 3″ contained in the cable with the abnormality sign detection function according to the third embodiment.

The detection line conductor 31″ in the detection line 3″ according to the third embodiment also includes inner elemental wires 3a that have a longer flex life and outer elemental wires 3b that have a shorter flex life and surround the bundle of the inner elemental wires 3a. Here, the inner elemental wires 3a are configured as bare wires exposing the conductive material. The outer elemental wires 3b are also individually configured as bare wires exposing the conductive material. However, the outer elemental wires 3b are divided into a plurality of groups g, while each of the groups g is surrounded by a dividing insulation layer 3e made of an insulating material. The outer elemental wires 3b constituting each group g surrounded by the dividing insulation layer 3e are not insulated from each other, but are insulated from the outer elemental wires 3b constituting the other groups g by the dividing insulation layers 3e. The outer elemental wires 3b are arranged around the bundle of the inner elemental wires 3a, keeping the groups g surrounded and defined by the dividing insulation layers 3e as units. The dividing insulation layers 3e may take any form to cover the groups g of the inner elemental wires 3a, such as extruded resin covering layers, enamel coating layers, sheets of insulating material such as paper or resin wrapped around the groups g, or tubes of such insulating material applied over the groups g.

When the detection line conductor 31″ is subjected to repeated bending or vibration, such as bending of the entire cable, the outer elemental wires 3b break earlier than the inner elemental wires 3a because the outer elemental wires 3b have a shorter flex life and because the outer elemental wires 3b are located in a more exterior area in the detection line conductor 31″. By detecting the breaks of the outer elemental wires 3b through changes in the characteristic impedance, it is possible to detect that fatigue has been accumulated also in the wire conductors of the target wires and that signs of wire breakage have occurred in the target wires. In an inspection for signs of wire breakage, a measurement of the characteristic impedance may be performed on the outer elemental wires 3b using the inner elemental wires 3a as a ground line, or may be performed on the detection line conductor 31″ as a whole, which includes the outer elemental wires 3b and the inner elemental wires 3a together, using a ground potential outside the cable. In the former case, the use of an external ground potential can be eliminated, while in the latter case, it is possible to detect the signs of wire breakage in at least two stages through the phenomenon where the inner elemental wires 3a break after the outer elemental wires 3b when loads are repeatedly applied due to bending or vibration.

In the third embodiment, unlike the first embodiment described above, the outer elemental wires 3b are not insulated individually. Thus, even when the outer elemental wires 3b break in a stepwise manner, it is difficult to detect the stepwise breaks of the outer elemental wires 3b one by one through changes in the characteristic impedance. However, it is possible to detect the breaks of the outer elemental wires 3b in a stepwise manner unit by unit, regarding each of the groups g defined by the dividing insulation layer 3e as a unit. In other words, when all of the outer elemental wires 3b constituting one of the group g break, a clear change may occur in the characteristic impedance measured on the outer elemental wires 3b as a whole, even when all of the outer elemental wires 3b constituting the other groups g have not broken. Thus, by detecting stepwise changes in the characteristic impedance, it is possible to detect the degree of urgency of signs of breakage in the target wires, distinguishing the signs into multiple stages whose number corresponds to the number of the groups g of the outer elemental wires 3b at the maximum (e. g., six stages at the maximum when the detection line 3″ shown in the figure is used).

The third embodiment can be preferably adopted when the degree of urgency of the signs of breakage in the target wires does not need to be judged with such a high resolution that the break of every outer elemental wire 3b can be distinguished, but is desired to be judged with certain degree of accuracy. In the case where bending of the cable does not occur equally in all directions but occurs frequently in one or some of the directions, particularly large loads are applied to the detection line conductor 31″ at a position corresponding to the inner side of the bent shape. Then, a situation in which all of the outer elemental wires 3b constituting one group g break is more likely to occur in the group g at such a position than in the other groups g. In this case, the detection line conductor 31″ according to the third embodiment, in which the groups g of the outer elemental wires 3b are mutually insulated, can be used to detect the signs of breakage in the target wires due to bending or vibration in a stepwise manner effectively.

It is also possible to use the outer elemental wires 3b with different flex lives between groups. In this case, breaks of the outer elemental wires 3b preferentially occur in the group g including the outer elemental wires 3b with a shorter flex life, whereby changes are more likely to occur in the characteristic impedance due to the breaks of all of the outer elemental wires 3b within the group. For example, when a cable includes multiple target wires 2 having different flex lives, like the power wires 2A and 2B and the communication wires 2C and 2D shown in FIG. 1, the detection line conductor 31″ may be configured to include two types of groups g. One of the groups g includes outer elemental wires 3b with a shorter flex life and can suitably detect the signs of breakage in the target wire(s) with a shorter flex life, like the power wires 2A and 2B, whereas the other of the groups g includes outer elemental wires 3b with a longer flex life and can suitably detect the signs of breakage in the target wire(s) with a longer flex life, like the communication wires 2C and 2D. Then, it is possible to detect signs of breakage in the target wires with different flex lives distinguishing the target wires through the stepwise changes in the characteristic impedance of the detection line conductor 31″ corresponding to breaks of the outer elemental wires in the individual groups g.

In this case, it is preferable that each target wire in which signs of breakage are intended to be detected and a corresponding group g of outer elemental wires 3b suitable for detecting the signs of breakage in the target wire should be arranged in close proximity to each other within the cable with the abnormality sign detection function.

The foregoing description has been presented for a detailed illustration of the embodiments of the present disclosure; however, the present invention is not limited by the above-described embodiments, and modifications and variations are possible as long as they do not deviate from the principles of the present invention.

### Description of Reference Numerals

1 Cable (with abnormality sign detection function)
2 Target wire
2A and 2B Power wire
2C and 2D Communication wire
21 (21A-21D) Wire conductor
22 Wire covering
3, 3′, and 3″ Detection line
31, 31′, and 31″ Detection line conductor
32 Detection line covering
3a Inner elemental wire
3b Outer elemental wire
3c Insulation layer
3d Inner-outer insulation layer
3e Dividing insulation layer
4 Tape layer
5 Sheath
51 Outer layer
52 Inner layer
G Wire group
g Group of outer elemental wires

1. A cable with an abnormality sign detection function, comprising:
a target wire comprising:
a wire conductor; and
a wire covering that covers the wire conductor; and
a detection line comprising:
a detection line conductor; and
a detection line covering that covers the detection line conductor, wherein
the detection line conductor, as a whole, has a shorter flex life than the wire conductor,
the detection line conductor comprises, as elemental wires:
inner elemental wires; and
outer elemental wires having a shorter flex life than the inner elemental wires,
each of the inner elemental wires is configured as a bare wire that exposes a conductive material, and
the outer elemental wires are arranged around a bundle of the inner elemental wires, insulated from the bundle of the inner elemental wires.

2. The cable according to claim 1, each of the outer elemental wires comprises:
a conductive material; and
an insulation layer that covers the conductive material, and
the outer elemental wires are insulated from each other.

3. The cable according to claim 1, wherein the bundle of the inner elemental wires is surrounded by an insulating material, and the outer elemental wires are arranged around the insulating material.

4. The cable according to claim 1, wherein the outer elemental wires are divided into a plurality of groups, and each of the groups is surrounded by an insulating material.

5. The cable according to claim 1, wherein the outer elemental wires comprise multiple types of elemental wires having mutually different flex lives, and the outer elemental wires of each type are insulated from those of the other types.

6. The cable according to claim 5, wherein among the multiple types of elemental wires as the outer elemental wires, the elemental wires having a shorter flex life are located in a more exterior area within the detection line conductor.

7. The cable according to claim 1, wherein the inner and outer elemental wires have mutually different flex lives by having a difference in at least one of a constituent material and a diameter.

8. The cable according to claim 1, comprising:
a power wire; and
a communication wire,
each of which constitutes the target wire.
